(19) United States
(12) Patent Application Publication
(10) Pub. No.: US 2012/0230076 A1
(43) Pub. Date: Sep. 13, 2012

(54) VOLTAGE BALANCING

(75) Inventors: Patrick Palmer, Cambridge (GB); Weiwei He, Cambridge (GB); Mark Snook, Cambridge (GB)

(73) Assignee: AMANTYS LTD., Cambridge (GB)

(21) Appl. No.: 13/330,564

(22) Filed: Dec. 19, 2011

(30) Foreign Application Priority Data
Mar. 7, 2011 (GB) 1103806.4

(51) Int. Cl. H02M 7/5387; H03K 3/00

(52) U.S. Cl. 363/132; 327/109

(57) ABSTRACT

This invention generally relates to voltage balancing among series-connected power switching devices comprising one or more insulated gate bipolar transistor (IGBT), and more particularly to a method controlling sharing of voltage among series-connected power switching devices, wherein at least one said device is an insulated gate bipolar transistor (IGBT), the method comprising: controlling the IGBT dependent on a reference signal and collector or emitter voltage of the IGBT such that during an off period of said IGBT said reference signal limits an absolute value of collector-emitter voltage of said IGBT to be within a range; and control to temporarily change during said limiting said reference signal from an initial value to a temporary clamp value to reduce said range, said change when each of said devices is in a substantially non-conducting state.

### FIELD OF THE INVENTION

This invention generally relates to static voltage balancing among series-connected power switching devices, which preferably comprise one or more insulated gate bipolar transistors (IGBTs) or similar (e.g., JFETs, MOSFETs, SiC transistors, etc.). More particularly, the invention relates to a method of controlling sharing of voltage among such devices, to a reference signal controller, a reference signal generator, an active voltage control circuit, and to a power switching circuit such as a DC-AC inverter or a power converter for motor control.

### BACKGROUND OF THE INVENTION

Insulated gate bipolar transistors (IGBTs) are used for a wide range of power applications, from power supplies, computers and locomotives, to high voltage transmission lines. In particular, IGBTs are advantageously used to control large currents by the application of low level voltages or currents, some IGBTs having ratings of, e.g., 1600V and 1200 A.

The use of a single high voltage IGBT in a system for switching medium or high voltages is generally undesirable, since a suitable IGBT may be costly and/or have slow switching speed. Such systems are generally more easily constructed using multiple IGBTs arranged in a series topology. In an example inverter, IGBTs may be stacked and placed between power supply rails to form a phase leg as shown for example in FIG. 8b, which may represent a single leg inverter or a phase leg of a multiple leg inverter. FIG. 8a shows a multiple phase leg inverter having two IGBTs stacked in each of the upper and lower sides of each phase leg. The provision of a plurality of IGBTs in series allows the overall voltage, e.g., across an inverter phase leg or across an off side of an inverter phase leg, to be split across the IGBTs, allowing lower voltage IGBTs to be used and/or application of a higher overall voltage.

Nevertheless, difficulties remain even when a series connection of IGBTs is used, for example in relation to reliability and/or cost. If the overall voltage is not shared equally among the series IGBTs in the off (i.e., substantially non-conducting) state, lifetime of the IGBTs supporting a greater share of the overall voltage may be reduced. Even where additional circuitry is provided to improve the control of the IGBTs, this generally does not ensure perfect equality of shared voltage amongst the IGBTs and adds to the cost, power consumption, size and/or complexity of a power switching circuit comprising the series IGBTs.

Voltage balancing of an IGBT series connection generally focuses on dynamic voltage balancing, i.e., voltage balancing during switching transients. For example, snubber circuits may be used to assist and/or delay the switching of individual devices. However, these circuits generally increase the overall switching time of the series connection, may add to circuit size and/or cost and/or may result in losses that are difficult to recover. Moreover, circuits focused on dynamic voltage balancing generally do not achieve perfect equality of voltage sharing in the interval between switching events.

Thus improvements in static voltage balancing remain desirable, even in the presence of dynamic voltage balancing circuitry, to improve voltage balancing of series IGBTs when they are controlled to be in the off-state. This is the case since, for example, where large IGBT current and voltage occurs during a switching transient, the first IGBT to turn off may end up supporting a disproportionately large share of the overall voltage during the off state. The unequal voltage sharing may result in higher collector-emitter voltage in one or more of the IGBTs during the off-state such that the IGBT(s) have reduced reliability and/or operate beyond their safe operating limits. Thus, it may be advantageous to apply static balancing to redistribute the voltage more equally across series-connected IGBTs.

Static voltage balancing may be improved by paralleling a large voltage-divider resistor across each IGBT. However, there are several disadvantages of such paralleling. One disadvantage is that the paralleled resistor may cause extra power losses. A second disadvantage is that the value of the voltage-divider resistor generally has to be chosen very carefully: if the value is too big, the voltage sharing may be poor; conversely, if the value is too small, the power losses may be too high. A further disadvantage is that the use of extra components such as voltage-divider resistors and capacitors may reduce the robustness of the system. Further still, for IGBTs having a current tail following turn off (this depends on their design), the tail current effectively gives them a high leakage current for a period after turn off, further complicating the choice of voltage-divider resistor.

Active voltage clamping circuits, for example using a zener diode voltage reference, are available. Such circuits may prevent series IGBTs operating beyond their safe operating limits by limiting IGBT collector voltage. However, the individual IGBTS may nevertheless operate under sufficiently different current-voltage conditions in the nominal off-state of the series connection that reliability of the series connection of IGBTS as a whole may be significantly degraded.

Thus, there remains a need for improved static voltage balancing among series-connected power switching devices. Such improvement may concern, inter alia, increased reliability of IGBT switching, scalability (e.g., allowing a greater number of IGBTs to be connected in series), cost, size, complexity, efficiency (i.e. low power dissipation, e.g., by reducing switching losses), and/or quality of output voltage and current waveforms. etc. Similar improvements may be advantageous for voltage balancing among series connected JFETs, MOSFETs, Silicon Carbide transistors, etc.

For use in understanding the present invention, the following disclosures are referred to by way of useful background information:
International patent application publication WO2008/032113, published Mar. 20, 2008, applicants and inventors Patrick Palmer et al.;
International patent application publication WO97/43832, published Nov. 20, 1997, applicants and inventors Patrick Palmer et al.;
US patent application US2005253165, published Nov. 17, 2005, inventors Pace and Robins;
Semikron application manual, available at section 3.2.7 of http://www.fer.hr/_download/repository/SEMIKRON_APPL_MANUAL.pdf;
“Commutation in a High Power IGBT Based Current Source Inverter”, M. Abu-Khaizaran and P. R. Palmer, IEEE PESC07, pp. 2209-2215, Orlando, Fla., USA, 17-21 Jun. 2007).
United States patent application publication US2009/0296291 A1.
Chinese patent application publication CN101478143 A.
Chinese patent application publication CN101483334 A

### SUMMARY OF THE INVENTION

According to a first aspect of the invention, there is provided a method of controlling sharing of voltage among series-connected power switching devices, wherein at least one said device is an insulated gate bipolar transistor (IGBT), the method comprising: controlling the IGBT dependent on a reference signal and collector or emitter voltage of the IGBT such that during an off period of said IGBT said reference signal limits an absolute value of collector-emitter voltage of said IGBT to be within a range; and control to temporarily change during said limiting said reference signal from an initial value to a temporary clamp value to reduce said range, said change when each of said devices is in a substantially non-conducting state.

Generally, the IGBT is considered throughout this specification to be an re-channel IGBT. However, as the skilled person reading this specification will appreciate, the invention is further applicable to p-channel IGBT control.

The range may be restricted by the reference signal only at one end, e.g., the limiting may merely set an upper or lower limit to the collector-emitter voltage, e.g., by determining a threshold beyond which the collector or collector-emitter voltage cannot pass; thus the limiting does not necessarily mean that the collector or collector-emitter voltage is at a threshold set by the reference signal. Furthermore, the reduction in the range may merely narrow the range by reducing a maximum level which the collector or collector-emitter voltage may not exceed (i.e., in embodiments without influencing any minimum collector-emitter voltage).

Preferably, the temporary change control is implemented by a control circuit acting on a reference signal, or by a reference signal generator that generates the reference signal controlled to have the temporary change ab initio. The reference signal including the temporary change may be input to an AVC or CAVC circuit, for example as VREF of FIG. 1 or 2.

The temporary change control may be applied to reference signal(s) of one or more, e.g., all, of the series power switching devices in the off state, .e.g., all such devices in an inverter leg, or in an off side of an inverter leg. The change may be applied shortly after a last one of these devices has been turned off.

The reference signal may have a waveform such as shown in various figures of the present specification, i.e., substantially pulse-like to provide transitions to and from the off period, the limiting and temporary change occurring during the off period. However, in an embodiment the reference signal may have any waveform shape providing it comprises at least an off period for maintaining the off state of the IGBT, however long this period has lasted and/or will last. (“Off period” and “clamping period” are used interchangeably throughout this specification and correspond to a period throughout which the device is being controlled to be in a substantially (e.g., completely, or conducting less than ˜1 to ˜2% of the on state current—disregarding any change of off-state current during the temporary change) non-conducting state, i.e. off state, e.g., as shown by the ‘Off’ period between reference signal transitions in FIGS. 3, 4, 6, 7).

Optionally, the change is a voltage reduction of said reference signal and said initial value is a maximum voltage value of said reference signal during said limiting, for example where the IGBT is n-channel. However, the change and initial value may alternatively be an increase and a minimum, for example where the IGBT is p-channel. (The skilled person reading this specification will appreciate that that reference signal and temporary change may depend on, e.g., a number and/or arrangement of inverting amplifiers and/or non-inverting amplifiers between the reference signal and IGBT control terminal (gate)).

More specifically, the temporary change is preferably a reduction of the reference signal from, and subsequent return to, a particular value such as the initial value. The initial value is preferably a value for maintaining an off state of the IGBT during an increase in the shared voltage, e.g., due to a transient or ripple, more preferably while limiting the IGBT to a safe operating region. The shared voltage may for example be at least a portion of a supply rail of an inverter for DC-to-AC conversion, a supply rail of an electric car, or of a High Voltage Direct Current (HVDC) line generally used for long-distance transmission, etc.

The series-connected power switching devices may comprise one or more IGBTs, for example may be a chain of IGBTs or may be one or more IGBTs in a chain with one or more other power switching devices, e.g., MOSFET(s), JFETs, SiC transistors, etc. (References throughout this specification to an IGBT device may be considered to refer to a single IGBT or to an IGBT module comprising an IGBT and a freewheel diode, which is typically found in parallel with the IGBT in a module, to reduce damage such as due to flyback).

The temporary clamp value preferably limits the collector-emitter voltage to a voltage substantially equal to (e.g., within ˜95-˜105% or ˜98-˜102% or exactly equal to) said shared voltage (e.g., Vss) divided by the number of series-connected power switching devices sharing that voltage. Additionally or alternatively, the initial value of the reference signal is preferably at least about 10%, 20% or 30% greater or less than the temporary clamp value; the initial and temporary clamp values being relative to the value of the reference signal when the device is controlled to be fully on and/or relative to the IGBT emitter voltage—see use of emitter voltage as voltage reference in FIGS. 1 and 2). In this regard, we note that a level shifter may be used to provide the reference signal at an appropriate level depending on the position of the IGBT in the series connection.

The control dependent on the reference signal and collector and/or emitter voltage of the IGBT may be provided by controlling a gate-emitter voltage or gate current of the IGBT on the basis of comparison of a voltage dependent on the reference signal and a voltage dependent on collector voltage of the IGBT. Such gate control may involve the passing of a small collector-emitter current; however this is generally negligible. Examples of such IGBT control are shown by the Active Voltage Clamping (AVC) circuit of FIG. 1 and by the Cascade Active Voltage Clamping (CAVC) circuit of FIG. 2, which each show the reference signal being input to an amplifier VREF terminal. An embodiment may provide a said temporary change of the input reference signal of one of these circuits (such a change is not shown in FIG. 1 or 2). In such cases, and where the control is applied to a plurality of power switching devices (e.g. IGBTs) connected in series to share an overall voltage Vss (which may be a portion of, or full, voltage between supply rails), the temporary clamp value (e.g. relative to the value of the reference signal when the device is controlled to be fully on and/or relative to the IGBT emitter voltage) may be (or correspond to, taking into account attenuation or amplification in the VCE feedback path, e.g., the factor a as shown in FIGS. 1 and 2) substantially (including at least exactly) Vss/n, where Vss is the overall shared voltage—disregarding transients and ripple—and n is the total number of series-connected power switching devices sharing Vss.

The initial value of the reference signal (e.g., VCLAMP as shown in the reference signal profiles of FIGS. 3, 4, 6, 7; the initial value may be relative to the value of the reference signal or the IGBT emitter voltage as described above) advantageously limits collector-emitter voltage of the IGBT during the clamping period, i.e., said off period (shown in the above profiles as the central period between ‘Turn-off’ and ‘Turn-on’). The initial value of the reference signal during the off period may be (or correspond to, taking into account attenuation or amplification in the VCE feedback path, e.g., the factor α as shown in FIG. 1) for example Vss/n+m %, where m is a safety margin in case of transients and/or ripple, e.g., m is about 5, 10, 15, 20 or 30, preferably 10%. As mentioned above, the initial value preferably limits the IGBT collector-emitter voltage to within a safe operating limit/range of the IGBT, .e.g., below a safe operating limit, for example a device rating, specification of manufacturer recommendation as defined in a datasheet of the IGBT.

To understand advantages of embodiments, it is noted that where a power switching device, e.g., IGBT, in a series connection supports for example Vss/n+m %, this may mean that another of the power switching devices supports Vss/n−m %. A difference of 2m % (20% where a safety margin of 10% is used in relation to voltage clamping) then exists between the voltages supported by the two devices. A device supporting the higher voltage between its collector and emitter terminals may thus be stressed more than the other and this may be detrimental to reliability of the whole series IGBT connection. In an embodiment, the temporary change, e.g., reduction, in the reference signal may however push the associated power switching device away from a state where it would be supporting more than Vss/n, e.g., where it is clamped at Vss/n+m %, such that the voltage shares of the two devices becomes more equal. Thus, an advantage of an embodiment may be to improve reliability and/or lifetime of the series connection as a whole.

Further in this regard, an embodiment may enhance scalability of a power switching circuit comprising the series chain of power switching devices. For example, where a leg of such a circuit has 100 IGBTs in series and unequal voltage distribution in the off state occurs such that 10 of these IGBTs are each supporting 10% more voltage than if the overall voltage were distributed equally, this may allow one of the IGBTs to support effectively zero volts (albeit in a substantially non-conducting state). Similarly, if 50 of the 100 IGBTs are operating at +10%, five of them may be operating at substantially 0V. Generally, the greater the number of power switching devices provided in the series connection, the greater the number of devices that may be operating at substantially 0V. Thus, even when clamping (e.g., using AVC or CAVC as described below) is implemented to prevent each IGBT voltage exceeding the overall voltage divided by the total number of series IGBTs+m % margin, where the number of IGBTs is large such voltage limiting may nevertheless allow significant differences in current-voltage operating conditions between individual IGBTs. This may be detrimental to reliability of the series connection as whole and thus may impose a limit on the number of IGBTs and overall supply voltage. By improving equality of voltage sharing, an embodiment may advantageously increase or substantially eradicate this limit.

It is further noted that, since unequal voltage sharing of series-connected IGBTs may mean that the devices are in different states when turn-on is triggered, the turn-on times among the devices may be different. However, the temporary change, e.g., reduction of the reference signal in an embodiment may reduce residual charge in the IGBT to substantially equalize (e.g., to within 1, 2 or 5% difference) turn-on time of said IGBT and turn-on time of another of the power switching devices (e.g., another said IGBT). This may for example occur where two or more of the power switching devices are each controlled by a reference signal (respective or in common) having a said temporary change.

Regarding timing, the temporary change may occur anywhere within a finite said off period, for example may begin at, end at or extend over a mid-point of the off period, or may occur towards either end of the off period. The exact timing relative to the start of the off period may be fixed in advance, or may be determined on the basis of monitoring, e.g. of the IGBT collector current. For example, the exact timing of the start of the change may be determined on the basis of detecting within the off (clamping) period the tail current (e.g., value and/or rate of change) and/or a temporary increase in collector current due to leakage subsequent to the start of the off period (see FIG. 5c). The temporary change preferably begins substantially at (e.g., starts within +/−1, 2 or 5 microseconds of, and/or extends over) the middle or end of a tail current period of the IGBT. This may be advantageous for any device, e.g. Non Punch Through (NPT) IGBT, where tail current is significant; control of the temporary change position dependent on tail current shape and/or level may be advantageous even for a Punch Through (PT) type IGBT with significant tail current and/or tail current initial peak. For example, where a device has a relatively long tail current duration (depending on the type of IGBT), e.g., 100 microseconds, the shape of the tail current may be used advantageously to determine the timing (position) of the temporary change. The change may be applied after detection of an initial peak in tail current (e.g., detection of an increase and/or subsequent decrease to a lower, more stable current value) after the start of the off period, e.g., at 1 microsecond after the start of the off period.

It is further noted regarding timing that there may be a plurality of the temporary changes of a particular reference signal at different respective times during a single off period. As for the case of a single temporary change within the off period, the exact timing and number of these temporary changes may depend on the nature of the overall supply voltage, e.g., inverter supply rail, electric car supply rail, HVDC, etc., and/or may be determined on the basis of monitoring (e.g., voltage, current within the series connection, and/or temperature).

Regarding duration, and considering application of an embodiment for example in an inverter, a said off period may last for about, e.g., 5, 8, 10, 20, 50, 100 or 200 microseconds. The temporary change preferably lasts for less than about 10% of the off period, more preferably less than 5%. The duration of the temporary change for any off period duration may be for example be less or equal to about 1 or 2 microseconds, more preferably less than or equal to about 5, 8 or 10 microseconds.

Returning to discussion of the control mechanism, each of the series-connected power switching devices (including the IGBT) may have a separate control loop for active clamping (e.g., AVC or CAVC). Each of a plurality of such devices may be controlled dependent on the same reference signal. Additionally or alternatively, a plurality of the reference signals may be provided for controlling respective groups of one or more of the devices, at least one of the provided reference signals being temporarily changed during it's off (clamping) period. Where a plurality of reference signals for the series connections each have a said temporary change, the reference signals preferably synchronized to have coincident off and/or temporary change periods. Preferably, the temporarily changes are performed substantially simultaneously (e.g., within about 1 microsecond of each other) for each of the reference signals. However, the temporary changing of one or more of the reference signals may be performed at a different time during a synchronized (i.e., same start and end time) off period, relative to the temporarily changes of other(s) of the reference signals. Thus, the reference signals may be controlled so that their respective temporary changes are synchronized, or they may be controlled individually so that the relative timings of the respective temporary changes are changed cycle by cycle.

In an embodiment, a said temporary change may be applied only to a selected one or more of the series connected devices, e.g., the IGBT(s), in a particular turn-off/turn-on cycle, depending on monitoring of conditions within or ambient to the series connection, such as voltage (e.g., device collector and/or collector-emitter voltage), current (e.g., device collector current), temperature (device and/or ambient), etc. For example, only device(s) that are supporting greater than Vss/n (Vss being the shared voltage and not necessarily the full voltage between supply rails) and/or whose VCE voltage is being actively suppressed by an associated reference signal (e.g., having a said initial value) may have temporary change(s) applied to their corresponding reference signal(s). As for all instances of monitoring described herein, this monitoring may allow IGBT gate drives to be controlled to react to changing conditions such as device degradation and/or temperature. Thus, monitoring may be applied to a selection of or all power switching devices in a single or multiple-leg inverter; in embodiments such an inverter may have more than, e.g., 50 or 100 or even more such devices. Each device may be monitored individually to determine whether and/or when a temporary change should be applied to a reference signal provided in respect of that device.

Thus, where a plurality of the reference signals are provided, one or more may be selected to have the temporary change applied to it, the selection on the basis of monitoring at least one voltage in the series connection, and the temporarily changing performed on the or each of the selected reference signals during an off (clamping) period which is preferably synchronized across the reference signals. Such a monitored voltage may for example be a collector-emitter voltage or collector voltage of any power switching device in the series connection.

The method may be advantageous for improving reliability under rapidly and/or widely changing conditions, e.g., of load current or temperature. As an example, the method may comprise determining, on the basis of monitoring the shared voltage, load current or a temperature such as temperature of a the IGBT or ambient temperature, any one or more of: said initial value; said temporary clamp value; depth or height of the temporary change of the reference signal (i.e., difference between the initial value and temporary clamp value); duration of said off period; duration of said temporary change; start time of said temporary change; frequency of occurrence and/or number of occurrences of said temporarily changing of said reference signal within a said off period. Such determination may be performed in respect of the, each or any one or more said reference signal(s), depending on whether an embodiment provides one or more reference signals.

Additionally or alternatively in an embodiment providing one or more reference signals, there may be provided the method, comprising determining, on the basis of monitoring the shared voltage or a temperature such as temperature of a said IGBT or ambient temperature, any one or more of: for each of the reference signals, whether to perform a said temporary change during its said off period; and for each of the reference signals when to perform a said temporary change during its said off period. Similarly as above, such determination may be performed in respect of the, or each or any one or more of a plurality of, said reference signal(s). Where an embodiment makes such a determination as to whether to perform the temporary change, if the determination is negative the embodiment may automatically check again after a fixed period, e.g., 10 us, whether to apply the temporary change at a later time.

The invention further provides processor control code (i.e. a non-transitory computer-readable medium of program instructions) to implement the above-described method comprising any one or more of the above optional features, for example on an embedded processor. The code may be provided on a carrier such as a disk, CD- or DVD-ROM, programmed memory such as read-only memory (Firmware), or on a data carrier such as an optical or electrical signal carrier. Code (and/or data) to implement embodiments of the invention may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language such as Verilog (Trade Mark) or VHDL (Very high speed integrated circuit Hardware Description Language). As the skilled person will appreciate such code and/or data may be distributed between a plurality of coupled components in communication with one another.

According to a second aspect of the invention, there is provided a reference signal controller for applying a temporary change to a reference signal, said reference signal for voltage clamping an IGBT such that during an off period of said IGBT said reference signal limits collector-emitter voltage of the IGBT to be within a range, the reference signal controller arranged to temporarily change during said limiting said reference signal from an initial value to a temporary clamp value, said temporary change for controlling sharing of voltage among series-connected power switching devices including said IGBT when said devices are each in a substantially non-conducting state.

As for the above-described method, the devices may comprise a plurality of IGBTs, e.g., may be a chain of series-connected IGBTs. The reference signal controller may be implemented as a stand-alone unit (FIG. 12, block 1) to be coupled to a reference signal generator (FIG. 12, block 2) such as is shown in FIG. 1 or 2, or may be integrated with such a generator preferably in a power switching circuit (FIG. 12, block 4) such as an inverter. The reference signal controller may have an input to receive the reference signal from the generator, and an output to pass the temporarily changed signal to the remainder of the IGBT control circuitry. Thus, the controller may for example comprise a controllable attenuator to provide the temporary change of the received reference signal. Alternatively, and as shown in FIG. 12, the reference signal controller may be configured to provide an input to the generator to temporarily shift the level of the reference signal, e.g., may be coupled to a reference voltage input of a digital-analogue converter of a reference signal generator.

Regarding timing, the controller is preferably configured to trigger, e.g., using a timer, the temporary change at substantially a mid-point, or to extend over a mid-point, of the reference signal off (clamping) period, or nearer either end of the off period. Such triggering may be in response to, for example, monitoring conditions such as, e.g., voltage and/or current within the series connection, and/or temperature; such monitoring may further be used to determine the depth and/or length of the temporary change. The reference signal controller preferably comprises trigger circuitry, e.g., a tail current monitor, configured to ensure that the temporary change is substantially, e.g., exactly, at the end of a tail current period of said IGBT, e.g., where the IGBT is NPT- or even PT-type with tail current. Additionally or alternatively, the reference signal controller may comprise trigger circuitry (e.g., comprising a timer) to trigger a said temporary change that extends to the end of the off period immediately prior to turning on said IGBT by the reference signal.

A timer may be provided in the reference signal controller to control duration of the temporary change to be less than ˜10% of the off period, preferably less than ˜5% of the off period, and/or to be less than or equal to about 2 microseconds, more preferably less than or equal to about 5 microseconds. (A timer may similarly be provided in the reference signal generator to determine off period duration which may be, e.g., about 5, 10, 20, 50, 100 or 200 microseconds).

A power switching circuit, e.g., inverter for AC-to-DC conversion, comprising the reference signal controller and the series-connected power switching devices and preferably AVC or CAVC substantially as in FIGS. 1 and 2 may further comprise voltage divider resistors and/or capacitors coupled to the power switching devices, the resistors arranged to more equally distribute the shared voltage among the power switching devices.

There may further be provided a reference signal generator configured to generate a reference signal for an active voltage control circuit, said reference signal generator comprising the above reference signal controller arranged to apply said temporary change to said generated reference signal. Such a generator may be used to replace the generator shown in FIG. 1 or 2 such that reference signal differs from those shown in FIGS. 1 and 2 by comprising a said temporary change.

There may further be provided a reference signal generator configured to generate a reference signal for an active voltage control circuit, said reference signal for voltage clamping an IGBT such that during a off period said reference signal when input to a said active voltage control circuit limits collector-emitter voltage of said IGBT to be within a range, the reference signal having an off period comprising a temporary change of said reference signal from an initial value to a temporary clamp value, said temporary change for controlling sharing of voltage among series-connected power switching devices including said IGBT when each of said devices is in a substantially non-conducting state. Such a reference signal generator may be for example a digital to analogue converter digitally controlled and/or programmed to provide an output waveform having the profile of the reference signal comprising the temporary change (for example as shown in any of FIGS. 4, 6, 7). The generator may have any of the optional features of the above reference signal controller. Such a generator may be used to replace the generator shown in FIG. 1 or 2 such that reference signal differs from those shown in FIGS. 1 and 2 by comprising a temporary change.

There may further be provided an active voltage control circuit, e.g., AVC or CAVC circuit for example as shown in FIG. 1 or 2, comprising the above reference signal generator.

There may further be provided a power switching circuit comprising any above-described reference signal controller or reference signal generator and further comprising the series-connected power switching devices including the IGBT, wherein the power switching devices preferably comprise a plurality of IGBTs, the power switching circuit comprising a plurality of active voltage control circuits each arranged to control a respective said IGBT dependent on said reference signal.

There may further be provided a power switching circuit such as in inverter, comprising any above-described reference signal controller or reference signal generator, and said series-connected power switching devices including the IGBT, wherein said power switching devices comprise groups of one or more IGBTs and a plurality of active voltage control circuits each to control a respective said IGBT, the power switching circuit arranged to provide a plurality of said reference signals, each said reference signal to control the active voltage control circuits of a said group, the reference signal controller to temporarily change at least one said reference signal during a said off period.

Such a power switching circuit may comprise a voltage monitor to monitor at least one voltage in said series connection, a selector to select one or more said reference signals on the basis of said monitoring, said reference signal controller arranged to temporarily change the or each said selected reference signal during a said off period. The monitored voltage may be for example at a collector-emitter or collector of a said IGBT.

Any one or more of the instances of monitoring referred to above in relation to the method, reference signal controller, reference signal generator, active voltage control circuit and power switching circuit and their optional features may be performed using communications to and/or from units for performing the monitoring. Thus, a controller may determine one or more feature(s), such as on which reference signal(s) (i.e., for which of the power switching devices) the temporarily changing will be performed during a given off/clamping period, the initial value of reference signal(s), the temporary clamp value(s), depth of the temporary change (s), duration of the clamping period(s) and/or of the temporary change (s); and/or frequency of occurrence and/or number of occurrences of temporarily change (s) within off/clamping period(s). This may be achieved by the controller polling monitoring units coupled to the series connection, e.g., to the power switching devices and/or points within the series coupling of such devices. The controller may determine the feature(s) to have different values in respect of different power switching devices, depending on differences in states of the devices indicated by the monitoring. In an embodiment, the controller may however be substituted with distributed control.

According to a further aspect of the present invention, there is provided a power switching device controller for controlling sharing of voltage among series-connected power switching devices, wherein at least one said device is an insulated gate bipolar transistor (IGBT), the apparatus comprising: means for controlling the IGBT dependent on a reference signal and collector or emitter voltage of the IGBT such that during an off period of said IGBT said reference signal limits an absolute value of collector-emitter voltage of said IGBT to be within a range; and means for control to temporarily change during said limiting said reference signal from an initial value to a temporary clamp value to reduce said range, said change when each of said devices is in a substantially non-conducting state.

Any of the above reference signal controller, reference signal generator, active voltage control circuit, power switching circuit, inverter, or power switching device controller may be provided, wherein said IGBT is replaced with a JFET, MOSFET or SiC transistor, and said collector-emitter voltage is a drain-source voltage.

Any two or more of the above aspects, with or without any one or more of the optional features of the preferred embodiments, may be combined in any permutation. Further aspects of the invention comprise apparatuses corresponding to the above method embodiments and methods corresponding to the above reference signal controller reference signal generator, active voltage control circuit and power switching circuit embodiments. Still further aspects provide a reference signal controller, reference signal generator, active voltage control circuit or power switching circuit as described and/or illustrated herein.

Illustrative embodiments are defined in the appended dependent claims.

### BRIEF DESCRIPTION OF THE DRAWINGS

For a better understanding of the invention and to show how the same may be carried into effect, reference will now be made, by way of example, to the accompanying drawings, in which:

FIG. 1 is a schematic of a circuit comprising Active Voltage Control (AVC);

FIG. 2 shows a schematic of a circuit comprising Cascade Active Voltage Control (CAVC);

FIG. 3 shows a reference signal having, in order: On, Turn-off, Off, Turn-on, On phases;

FIG. 4 shows a reference signal with temporary clamp, i.e., a temporary change, in the clamp voltage during the off-state;

FIG. 5a, 5b, 5c, 5d, 5e show, respectively,: (a) waveforms associated with two IGBTs in series to both of which are applied the same reference signal with temporary clamp, i.e., temporary change in value of the reference signal, during the off-state; (b) a zoom-in of the turn-off of FIG. 5a showing the operation of the temporary clamp and subsequent improved voltage sharing; (c) as FIG. 5b (gate resistor Rg 1 ohm, RMOS 20 ohm), but showing instead of the reference, total diode voltage; (d) collector-emitter voltage of each IGBT and collector current of the IGBTs as previously shown in FIGS. 5a-c; and (e) the reference signal and collector current of the IGBTs as previously shown in FIGS. 5a-c. In FIGS. 5a and 5b, the reference signal is shown in yellow, the total IGBT string voltage is in pink/purple, the current in the series connection, i.e., IGBT collector current, is shown in blue, and the individual IGBT voltages are in green and orange (displayed at 0.5 kV/unit c.f. 1.0 kV/unit for the total string voltage); this applies similarly for all the measured waveforms shown in the drawings, i.e., FIGS. 5a, 5b, 9b, 10, 11, an exception being the yellow diode voltage trace of FIG. 5c;

FIG. 6 shows, in addition to a temporary clamp similarly as in FIG. 4, a change (reduction) in the reference signal immediately before turn-on;

FIG. 7 shows, in addition to a temporary clamp similarly as in FIG. 4, a temporary clamp reapplied before turn on with a different profile at turn-on;

FIGS. 8a and 8b show: (a) an example inverter comprising series-connected IGBTs; and (b) a single leg of the inverter of FIG. 8a (noting however that an inverter may have no more than one leg such as that of FIG. 8b);

FIGS. 9a and 9b show waveforms of clamping of two IGBTs in series without temporary clamping, i.e., without a temporary change, the setups of FIGS. 9a and 9b comprising a rig similar to that of FIG. 5 and having 220 pF and Rf1=10K as values of resistor and capacitor in the potential divider of the VCE feedback loop;

FIG. 10 shows waveforms for a circuit using AVC, the circuit comprising two IGBTs in series;

FIG. 11 shows waveforms of hard-switching of two series-connected IGBTs (no control applied); and

FIG. 12 shows a block diagram of circuitry within a power switching circuit such as an inverter.

### DETAILED DESCRIPTION OF EMBODIMENTS

The following introduces unclamped and clamped IGBT switching, before proceeding to describe static voltage balancing by applying a specially designed temporary clamping reference signal during IGBT off-state, i.e., a reference signal comprising a temporary change otherwise referred to as a ‘temporary clamp’.

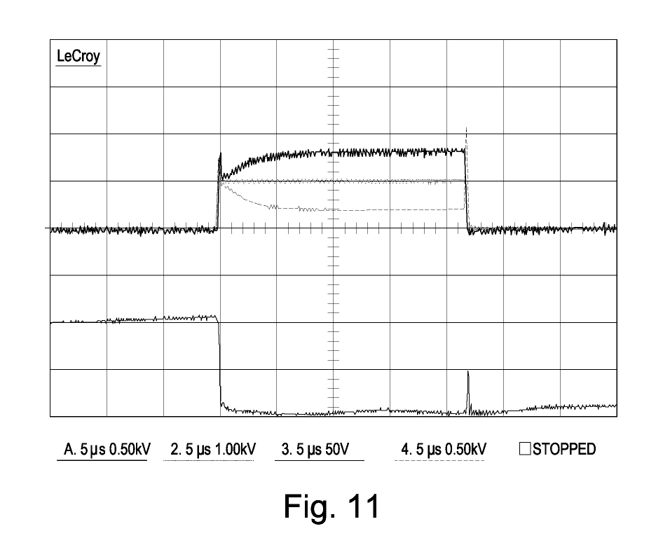

FIG. 11 shows waveforms associated with hard-switching of two IGBTs in series, i.e., switching without any clamping or resistor voltage divider, with a normal square wave at the IGBT gates, no gate resistors and using VGE feedback but not dV/dt feedback (see CAVC circuit of FIG. 2). More specifically, no feedback control (e.g., AVC—see below) is applied, i.e., the IGBT operation is open loop. As shown, the voltages across the two IGBTs diverge throughout the off period, although the total voltage remains constant during the off time. In an unclamped circuit, there is a risk that an IGBT will support a greater share of the overall voltage such that the IGBT is outside its safe operating limit.

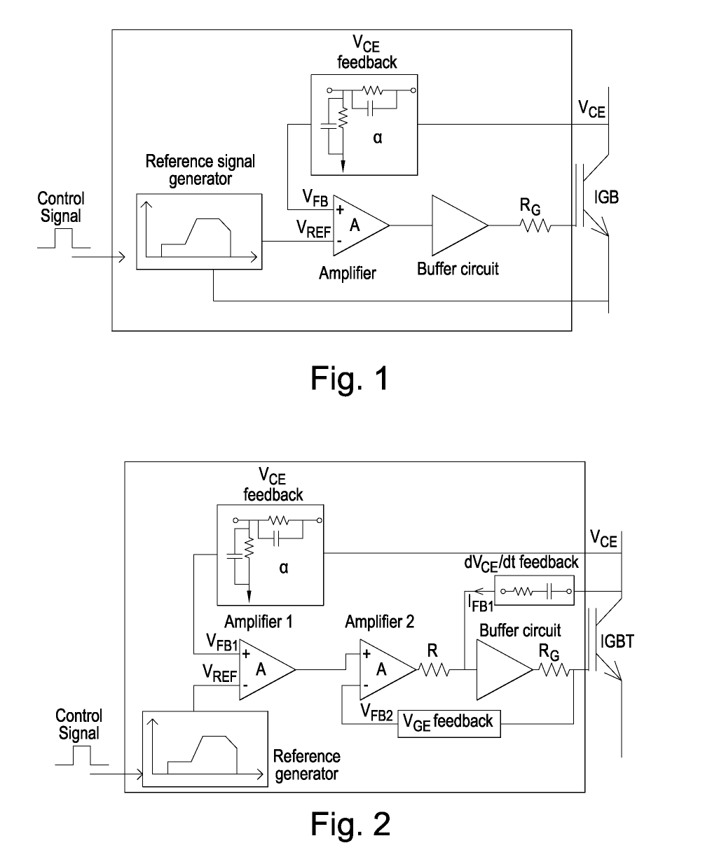

Techniques for controlling IGBT switching include voltage, current, dv/dt, and/or di/dt open or closed loop feedback control. An example of closed loop control is shown by the schematic of an Active Voltage Control (AVC) technique in FIG. 1. Such a closed loop control circuit may be applied to each of a plurality of IGBTs connected in series to share an overall voltage. The feedback loop achieves direct control of the IGBT's collector-emitter voltage VCE by comparing the feedback voltage VFB with the pre-set reference VREF. The AVC regulates the IGBT switching according to the reference signal through this direct control. The VCE feedback loop is a potential divider circuit with a ratio α for VCE sensing and scaling. The error signal from differential amplifier is amplified with a gain of A and then applied to the buffer circuit to amplify the driving current and applied to gate via the gate resistor RG.

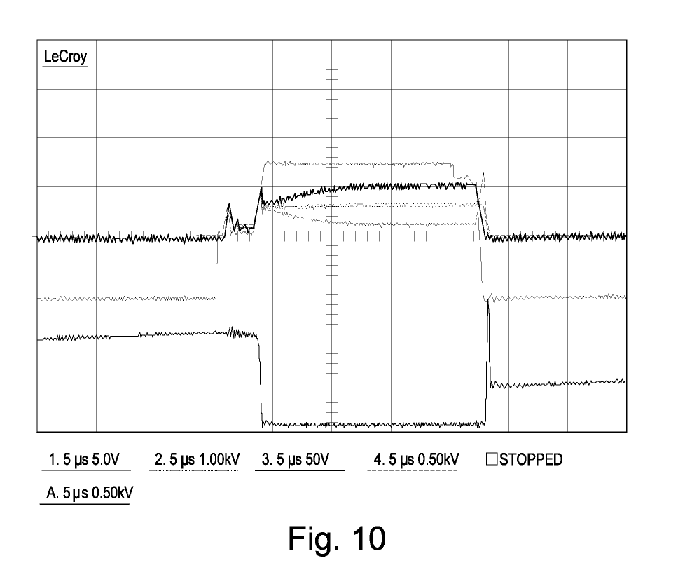

FIG. 10 shows waveforms for switching of two IGBTs in series with AVC applied to each IGBT, showing turn-off (see fall in collector current—lowest trace) followed by turn-on of current flow through the IGBTs. The reference signal is applied in common to the AVC circuits of the IGBTs. Neither of the IGBT voltages reaches the reference signal (uppermost trace), i.e., no clamping occurs. Moreover, the voltages across the two IGBTs diverge during the off period. Thus, there occurs unequal voltage sharing, which disadvantage may be overcome by an embodiment of the invention as described herein. FIG. 10 further shows, as seen in the lowest trace, that the IGBT collector current has tail current immediately after turn-off, the tail current related to removal of residual charge in the IGBT(s). Furthermore, FIG. 10 shows that, at turn-on, one of the IGBTs temporarily supports a disproportionately large amount of the overall shared voltage (see peak in the green trace at turn-on).

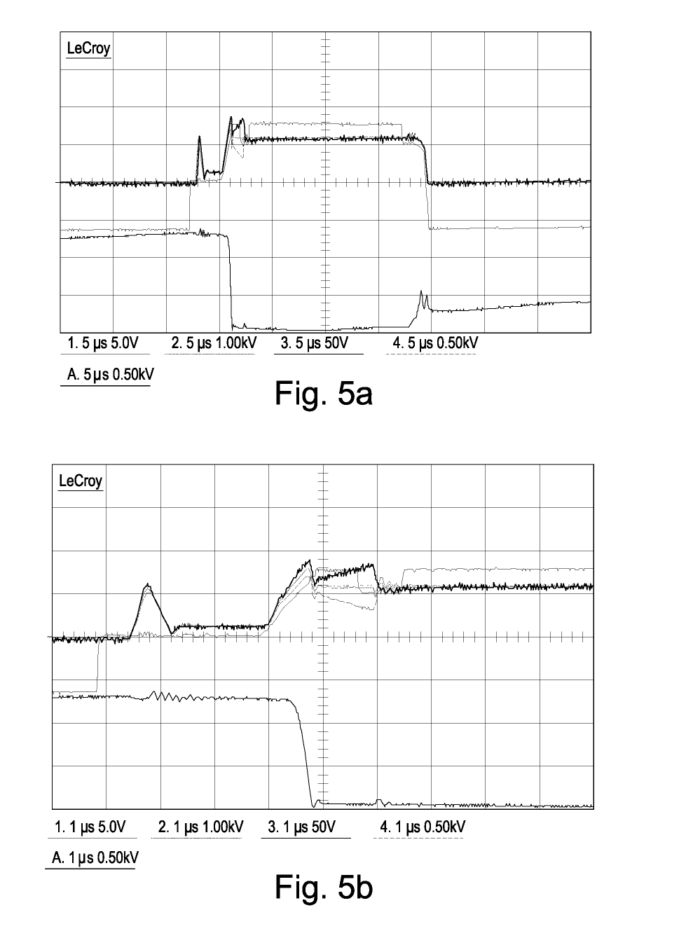

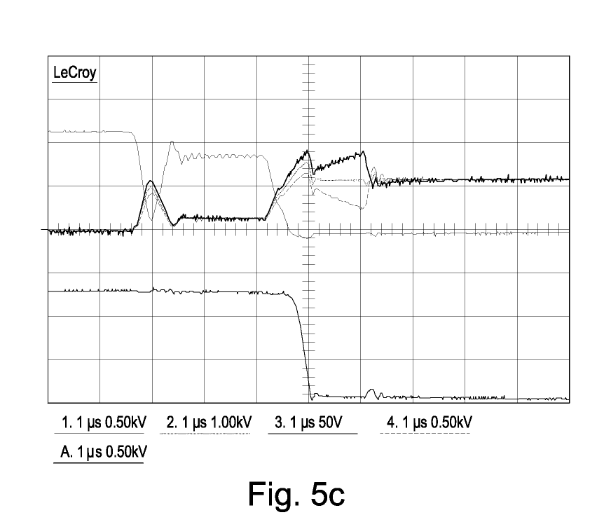

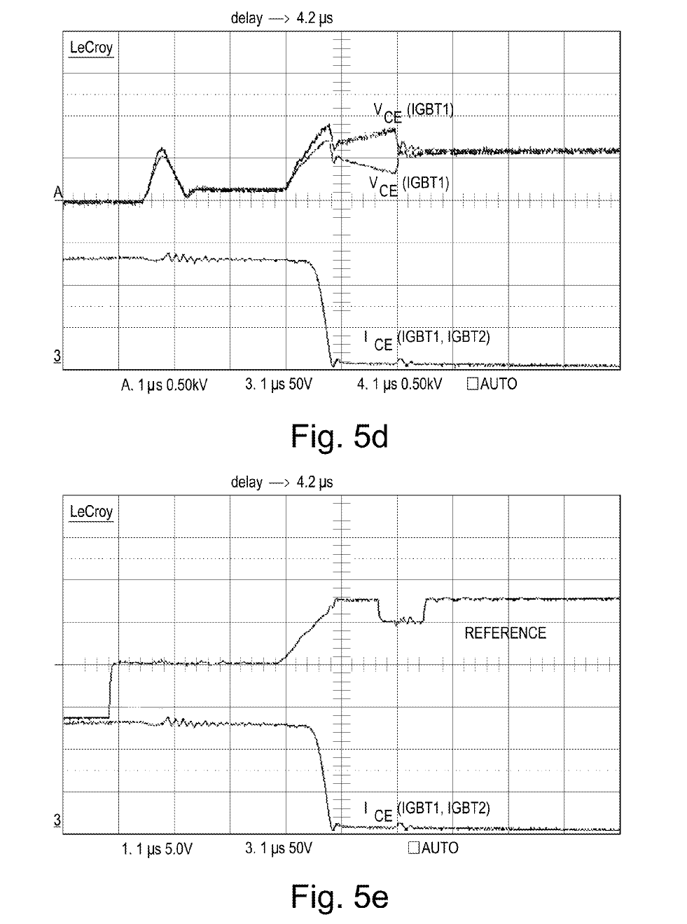

In more detail, different amounts of residual charge in the IGBTs at turn-off may cause divergence in the IGBT states during the off-period as shown by the traces, which diverge and then settle to respective values in FIG. 5. This may in turn mean that the IGBTs turn on from slightly different operating states, which may lead to different turn-on times (i.e., time between triggering of turn-on and existence of the fully conducting, on-state of an IGBT) and/or undesirable voltage-current conditions of IGBTs during turn-on. For example, the above disproportionately large amount of the overall shared voltage across one the IGBTs (see peak in the green trace at turn-on) may result in the turn-on time being different for individual IGBTs in the series connection.

Moreover, the difference between the respective values of the IGBT collector-emitter voltages at the end of the off period indicates unequal voltage sharing, which may reduce lifetime of the series connection of IGBTs. The device supporting higher voltage may suffer higher operating temperature and/or greater physical stress, which may lead for example to ageing of the device and/or cracking of the device packaging. Consequently, the lifetime of the two IGBTs combined may be reduced.

In comparison to AVC as described above, Cascade Active Voltage Control (CAVC) generally enhances the stability of the feedback system, increases the preciseness of voltage following, and/or reduces the switching power losses. In the CAVC of FIG. 2, the original AVC of FIG. 1 is still part of the scheme except that two more feedback loops, using the gate-to-emitter voltage VGE feedback and dVCE/dt feedback, are introduced to provide the system with nested feedback loops.

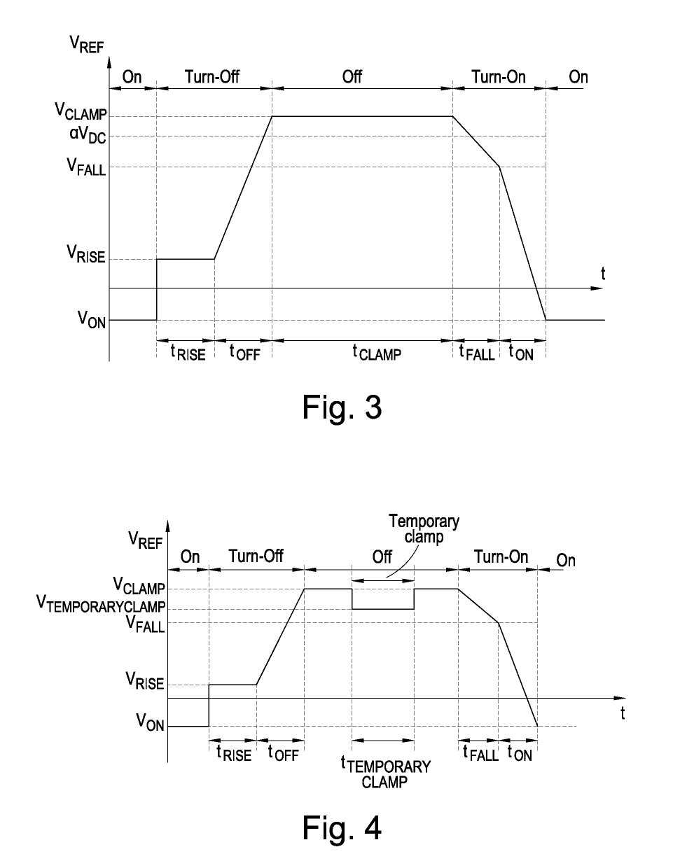

In relation to an embodiment, the profile of the reference signal VREF in such AVC techniques is of particular interest. FIG. 3 is an example of a reference signal for use in FIG. 1 or 2, the reference signal advantageously for ensuring safe operation of the IGBT coupled to the AVC or CAVC to which the reference signal is supplied. The excess in the reference signal above the relevant proportion of the supply voltage (FIG. 3: VDC) allows the IGBT voltage some margin to deviate from the exact proportion desired in the absence of any parallel voltage divider resistors or if the voltage sharing is not ideal despite the sharing resistors. The excess also allows some margin to maintain an off state should the total voltage across the string of IGBTs rise due to a supply voltage transient. Should the voltage on an individual IGBT deviate to the value of VOFF (or a value corresponding to VOFF taking into account ratio; FIG. 3), then the active voltage control loop operates and the voltage is clamped.

(A reference signal used in any embodiment may for example have a range of from −6V to 11.5V. The amplification ratio for VCE may be ˜100).

The above clamping techniques applied to series-connected IGBTs may however allow one or more of the IGBTs to have a low voltage and be fully off while others of the IGBTs are in a higher voltage off state. Moreover, at least one of the power switching devices may be clamped, i.e., limited by the reference signal, during an increase in the overall shared voltage for example due to a transient or ripple, while other(s) may be operating in an unlimited state, e.g., supporting substantially 0V. Where the IGBTs are in such different states, their respective control loops may be saturated differently; since it is generally difficult to pull a control loop out of saturation, the different states will generally remain for the remainder of a clamping period. Furthermore, the resulting different operational states of the IGBTs may cause considerable problems at turn on, as the IGBTs are in different states closer or further away from turn on into a high current. In such a case the voltage sharing may become extremely poor, with increased likelihood of an overvoltage in one or more of the series IGBTs. This generally is not satisfactory for reliable high power equipment. Even just unequal voltage sharing, wherein not all of the series-connected IGBTs operate in a true off state, may degrade at least long term reliability of the IGBTs. Such issues relating to different states before turn-on may arise with various clamping methods for series power switching devices such as IGBTs, MOSFETs, etc.

The use of parallel sharing resistors potentially offers a solution to the issues outlined above, but has disadvantages such as cost. Adapting AVC or CAVC to have a clamping voltage that follows the overall shared voltage (Vss) such that all IGBTs in a series connection always support exactly Vss/n (n=the total number of IGBTs in the series connection) is difficult due to transients in Vss.

In an embodiment of the invention, static voltage balancing may be achieved by applying during IGBT off-state a specially designed temporary clamping reference signal, i.e., a reference signal comprising a temporary change such that where the upper value of the reference (FIG. 3 VOFF) is reduced from a preceding ‘initial’ value for a short period. Such a ‘temporary clamp’ may be applied with various techniques including for example the AVC and CAVC described above, in particular as shown in FIG. 1 or 2.

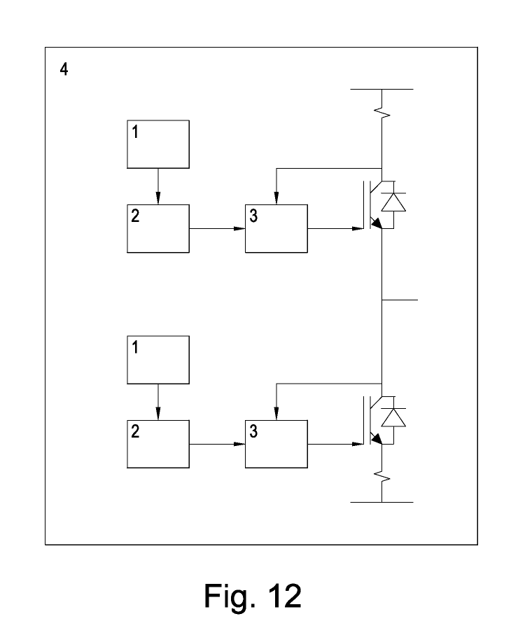

FIG. 12 shows a block diagram of circuitry within a power switching circuit embodiment 4, which may for example be an inverter. The power switching circuit comprises, inter alia, a plurality of IGBTs (two shown in FIG. 12, or more) connected in series, each IGBT coupled to an active voltage control circuit 3 (e.g., comprising AVC or CAVC circuitry as in FIG. 1 or 2), the active voltage control circuit 3 coupled to a reference signal generator 2 which in turn is coupled to reference signal controller 1. Any two or more of the elements 1-3 may be integrated in a single unit. As the skilled person will recognize, further circuitry not shown in FIG. 12 may be present, in particular further components such as one or more power switching devices may be present in either or both of the lines to VSS and 0V (which are interrupted with a zigzag symbol in FIG. 12 to indicate this). The references signal including temporary clamp (temporary reduction) is input to the active voltage control circuit 3 from the reference signal generator. In a slightly different embodiment, the reference signal generator 2 may comprise the reference signal controller 1, or the reference signal generator may be designed or programmed to generate.ab initio a reference signal exhibiting the temporary clamp (i.e., rather than the reference signal being generated without temporary reduction and being modified to have the reduction). Timing (start time and/or duration) of the clamping period of the reference signal and/or of the temporary clamp may be determined in respect of each reference signal, individually or together, by a further controller (not shown) within or external to the power switching device 4.

By applying a temporary clamp, i.e., temporary change such as reduction, to the reference signal, voltage sharing may be temporarily re-imposed as the IGBTs with a higher voltage have their voltage reduced, which may advantageously cause those IGBTs with a lower voltage to have their voltage raised, thereby sharing out the actual supply voltage more evenly.

The ‘temporary clamp’ is shown in FIG. 4 as a brief reduction in VREF, and may be advantageous when applied to one IGBT, or more preferably a plurality of IGBTs, in a series connection of power switching devices including the IGBT(s) extending between terminals of an overall shared voltage. For example, in the middle of the off-state of the devices, the reference signal has a temporary clamp state which is a reduced value of the reference lasting a relatively short period. The temporary nature of the reduction, i.e., the reference signal's reduction from and return to a particular value, may be advantageous for keeping the IGBT collector-emitter current within its short circuit current limit, which may be defined in the IGBT datasheet.

The temporary clamp may be triggered on the basis of monitoring an excursion in a control loop such as the AVC or CAVC control loop of FIG. 1 or 2, wherein the excursion may be indicative that the associated IGBT is being actively clamped (limited) by the reference signal. More specifically, the temporary clamp may be implemented by adding a comparator to detect a sign change of the output (referred to as ‘error signal’) of the amplifier of FIG. 1 or the amplifier ‘1’ in the circuit configuration of FIG. 2. When the (C)AVC is clamping the IGBT, VFB1=VREF so that the error signal is zero. When (C)AVC clamping is inactive, VFB1<VREF so that the error signal may be negative and large. Thus, (C)AVC clamping state may be detected by the added comparator and used to determine when and/or whether to apply a temporary reduction in the reference signal (which is shown in FIG. 2 as the controlled signal to be output from the reference generator). Where excursion monitoring is applied to each control loop associated with a respective IGBT, a temporary reduction may be applied to all of the series-connected power switching devices or selectively applied only to reference signal(s) received by the control loop(s) having the detected excursion(s).

In an embodiment, the temporary clamp is generally of such a short duration that it is unlikely to coincide with a supply voltage transient and should it do so the current rise rate will generally limit the peak current reached before the reference reverts to its previous higher value. Preferably, the temporary clamp period is also relatively short to avoid inaccuracies in the voltage division causing a significant current in the IGBT string.

Preferably, the temporary clamp is a dip in the off-state reference value. The value of the reduced reference signal during the temporary clamp is preferably set by the exact division of the supply voltage by the number of series-connected power switching devices, e.g., IGBTs.

Temporary clamp periods of around 5 microseconds for a high current device may be applied at multiple times during the VREF clamp signal with benefit. For example, the VREF signal of FIG. 4 may have more than the single temporary clamp shown within the Off period shown.

Furthermore, for different IGBTs the temporary clamp may be applied at preferential times relative to the initial turn off ramp.

Losses associated with the temporary clamp are generally minimal. Even if the temporary clamp turns on the IGBTs with the higher than desired voltages in an embodiment, very little current flows, since those IGBTs with a voltage below the desired level remain fully off.

The clamp is preferably temporary within the Off period shown in FIG. 4, to avoid a fluctuation in the supply voltage causing a full turn-on of the string of devices (generally at least one IGBT, or all IGBTs) and/or to fully establish a final off-state which can be maintained by high value voltage divider resistors or other means following successive applications of the temporary clamp, the number of cycles depending on the type of IGBT, the length of the off time and/or the requirements of the application.

FIGS. 5a and 5b show that the temporary clamp can push the different VCEs of the series-connected power switching devices together. Specifically, the temporary clamping pushes the higher VCE lower causing the lower VCE higher, as they all follow the reference. Thus, and as indicated above, the temporary clamp may advantageously cause the voltages across those IGBTs with a lower voltage to have their voltage raised thereby sharing out the actual supply voltage more evenly.

Looking at FIGS. 5a and 5b in more detail, the IGBT voltages are seen to diverge rapidly following turn off (signified by the series connection current falling substantially to zero). Some short time later the voltages are brought back together by the temporary clamp. The IGBT voltages cease diverging after the temporary clamp is removed. The temporary clamp may be improved in an embodiment by making it slightly longer than as shown in FIGS. 5a and 5b. The series connection current trace in FIGS. 5a and 5b shows that virtually no current flows during the temporary clamp period.

The position of the temporary reduction may for example be shortly after turn-off or shortly before turn-on of the power switching device(s). Generally, it is preferable to apply the temporary reduction to all series-connected power switching devices desired to be controlled off. For example, if the position is shortly before turn-on (e.g., within ˜10 us of turn-on), all of the devices may thus have a more similar ‘history’ and thus, for example, internal distribution of charge, prior to the turn-on. If shortly after turn-off (e.g., within ˜10 us of turn-off and/or earlier than ˜10 us before turn-on), it may however be preferable to apply the temporary reduction to all except, e.g., one, of the series-connected power switching devices desired to be controlled off, to be more certain that the series combination as a whole remains off, i.e., in a highly resistive, low current state. A controller may at any time be used to determine (for example on the basis of monitoring VCE voltages across the series connection) to which device(s) the reduction is applied; however this may be restricted to a middle portion of an Off period so that the above applies by default in respect of temporary reductions applied at positions shortly after turn-off and/or in positions shortly before turn-on.

More specifically, the position of the temporary clamp may be different according to the type of IGBT. For a Non-Punch Through (NPT) device, as the tail current time is quite long, the temporary clamping is preferably placed within and/or at the end of the tail current time. For a Soft Punch Through (SPT) device whose tail time is short, the temporary clamp may be placed very near to the ramp. The length of the temporary clamp may also depend on the device characteristics as well. If the device's power rating is small, which generally means it will respond to the reference signal very fast, the temporary clamp can be short, e.g., up to 2 microseconds, otherwise it should be longer, e.g., up to 5 or 10 microseconds. The value of the temporary clamp reduction is usually set as a small percentage of the proportional share of the operating voltage of the string. This may ensure that each of the devices connected in series maintains a similar operating voltage within a small band according to the original design.

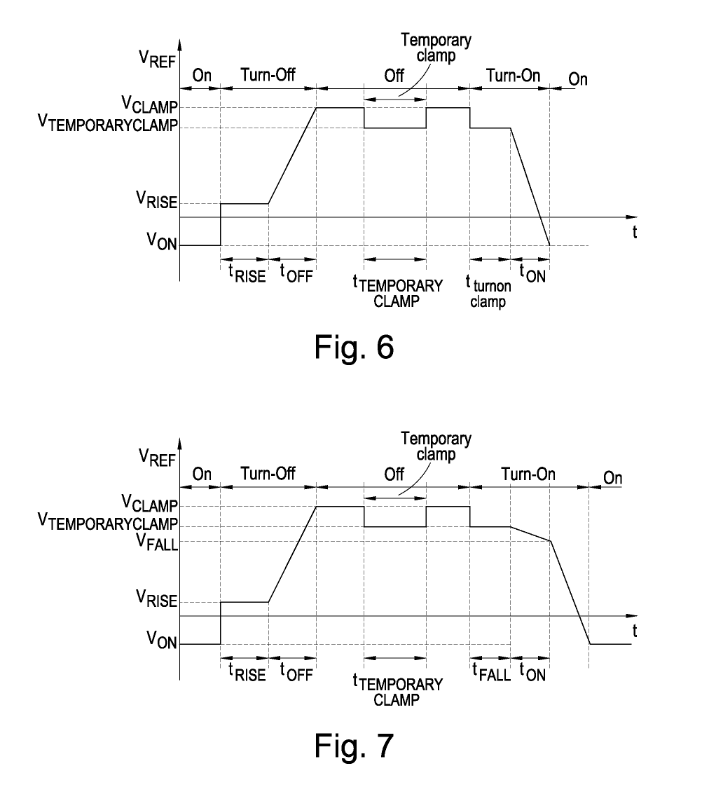

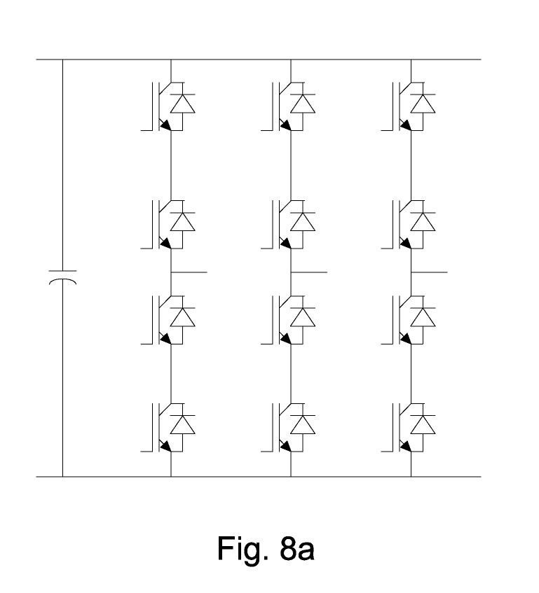

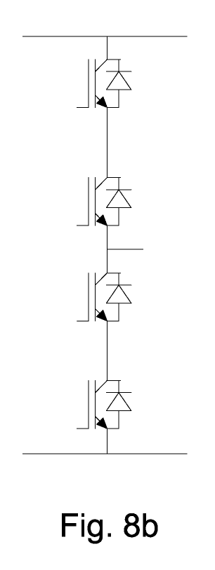

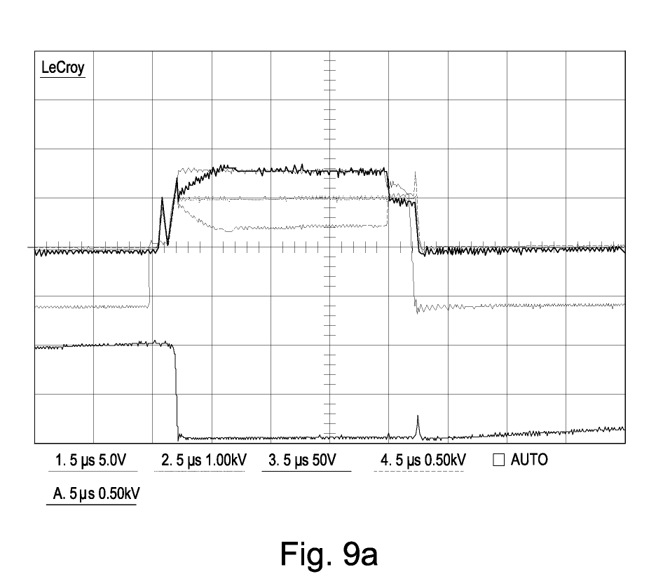

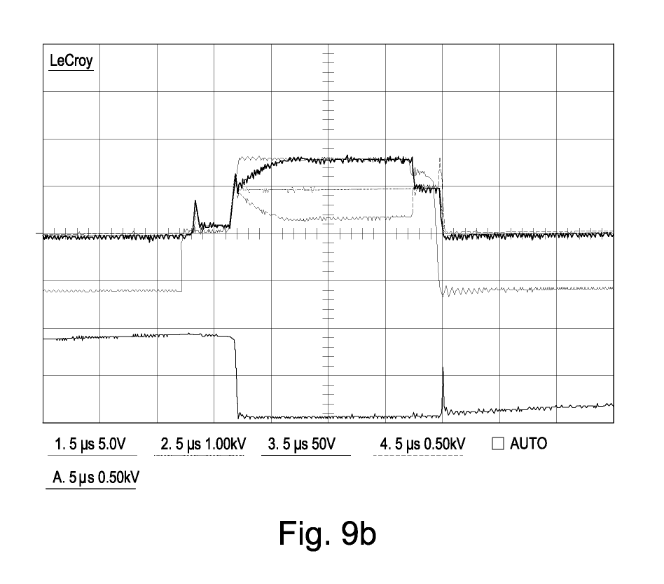

FIGS. 6 and 7 are two further examples of reference signals, which have different turn-on profiles such that, in addition to a temporary clamp as described above, the reference signal is reduced immediately prior to turn on to further ensure that the IGBTs are all in the same state at turn on.

Embodiments may be implemented in low voltage chips, computers, locomotives, high voltage transmission lines, motor control and inverters such as for renewable energy sources, e.g., wind turbines.

Feedback from the IGBTs, for example indicating detection of clamping, to a remote monitoring station enables performance to be monitored and advantageously early power transistor failure to be detected.

No doubt many other effective alternatives will occur to the skilled person. It will be understood that the invention is not limited to the described embodiments and encompasses modifications apparent to those skilled in the art lying within the spirit and scope of the claims appended hereto.

What is claimed is:

1. A method of controlling sharing of voltage among series-connected power switching devices, wherein at least one said device is an insulated gate bipolar transistor (IGBT), the method comprising the steps of:
controlling the IGBT dependent on a reference signal and collector or emitter voltage of the IGBT such that during an off period of said IGBT said reference signal limits an absolute value of collector-emitter voltage of said IGBT to be within a range; and
providing control to temporarily change during said limiting said reference signal from an initial value to a temporary clamp value to reduce said range, said change when each of said devices is in a substantially non-conducting state.

2. The method as claimed in claim 1, wherein said change is a voltage reduction of said reference signal and said initial value is a maximum voltage value of said reference signal during said limiting.

3. The method as claimed in claim 1, wherein said IGBT is an n-channel IGBT.

4. The method as claimed in claim 1, wherein said reference signal having said initial value limits said collector-emitter voltage to a safe operating limit of the IGBT.

5. The method as claimed in claim 1, wherein said reference signal having said temporary clamp value limits said collector-emitter voltage to a voltage substantially equal to said shared voltage divided by the number of said power switching devices.

6. The method as claimed in claim 1, wherein said initial value is one of either (a) at least 10% greater than said temporary clamp value, or (b) at least 20% greater than said temporary clamp value.

7. The method as claimed in claim 1, wherein said temporary change extends over a mid-point of said off period.

8. The method as claimed in claim 1, wherein said temporary change is substantially at the end of a tail current period of said IGBT.

9. The method as claimed in claim 1, wherein the temporary change has a duration less than or equal to one of either (a) about 2 microseconds or (b) less than or equal to about 5 microseconds.

10. The method as claimed in claim 1, wherein said temporary change has a duration of one of either (a) less than 10% of the off period or (b) less than 5% of the off period.

11. The method as claimed in claim 1, comprising performing said temporary change control multiple times during said off period.

12. The method as claimed in claim 1, wherein said power switching devices comprise a plurality of IGBTs, the method comprising said IGBT controlling to control each said IGBT dependent on said reference signal.

13. The method as claimed in claim 1, wherein said power switching devices comprise a plurality of IGBTs, the method comprising providing a plurality of said reference signals and comprising performing said IGBT controlling to control each said IGBT dependent on a respective said reference signal, the method comprising said controlling to temporarily change at least one said reference signal during a said off period.

14. The method as claimed in claim 13, wherein said control to temporary change is performed substantially simultaneously on each of said plurality of reference signals.

15. The method as claimed in claim 13, wherein during said off period a said control to temporarily change a said reference signal is performed at a different time relative to a said control to temporarily change another said reference signal.

16. The method as claimed in claim 13, the method comprising selecting one or more said reference signals on the basis of monitoring at least one voltage in said series connection, and performing said control to temporarily change on the or each said selected reference signal during a said off period.

17. The method as claimed in claim 12, wherein a said temporary change of a said reference signal reduces residual charge in said IGBT to substantially equalize turn-on time of said IGBT and turn-on time of another said IGBT.

18. The method as claimed in claim 1, comprising determining, on the basis of monitoring the shared voltage, IGBT collector current, and/or a temperature such as temperature of a said IGBT or ambient temperature, at least one of:
said initial value;
said temporary clamp value;
depth or height of the temporary change of the reference signal;
duration of said off period;
duration of said temporary change;
start time of said temporary change;
frequency of occurrence and/or number of occurrences of said temporary change control of said reference signal within a said off period.

19. The method as claimed in claim 13, comprising determining, on the basis of monitoring at least one of (a) the shared voltage, IGBT collector current, and (b) a temperature such as temperature of a said IGBT or ambient temperature, at least one of of:
whether to perform a said temporary change control of each said reference signal during a said off period, and
when to perform a said temporary change control of each said reference signal during a said off period.

20. The method as claimed in claim 1, wherein said IGBT is replaced with a JFET, MOSFET or SiC transistor, and said collector-emitter voltage is a drain-source voltage.

21. A non-transitory computer-readable medium including program instructions that perform the steps of claim 1.

22. A reference signal controller for applying a temporary change to a reference signal, said reference signal for voltage clamping an IGBT such that during an off period of said IGBT said reference signal limits collector-emitter voltage of the IGBT to be within a range, the reference signal controller arranged to temporarily change during said limiting said reference signal from an initial value to a temporary clamp value, said temporary change for controlling sharing of voltage among series-connected power switching devices including said IGBT when said devices are each in a substantially non-conducting state.

23. The reference signal controller as claimed in claim 22, wherein said change is a reduction and said initial value is a maximum value.

24. The reference signal controller as claimed in claim 22, wherein said IGBT is an n-channel IGBT.

25. The reference signal controller as claimed in claim 22, comprising trigger circuitry arranged to trigger said control to temporarily change said reference signal at a mid-point of said off period.

26. The reference signal controller as claimed in claim 22, comprising trigger circuitry arranged to trigger a further said control to temporarily change said reference signal such that said further controlled change extends to an end of said off period immediately prior to turning on said IGBT by said reference signal.

27. The reference signal controller as claimed in claim 22, wherein the reference signal controller comprises trigger circuitry arranged to determine timing of said temporarily changing to be substantially at an end of a tail current period of said IGBT.

28. The reference signal controller as claimed in claim 22, comprising a timer to control duration of the temporary change to be less or equal to one of either (a) about 2 microseconds or (b) less than or equal to about 5 microseconds.

29. The reference signal controller as claimed in claim 22, comprising a timer to control duration of the temporary change to be one of either (a) less than 10% of the off period or (b) less than 5% of the off period.

30. The reference signal controller as claimed in claim 22, wherein said IGBT is replaced with a JFET, MOSFET or SiC transistor, and said collector-emitter voltage is a drain-source voltage.

31. The reference signal generator configured to generate a reference signal for an active voltage control circuit, said reference signal generator comprising a reference signal controller as claimed in claim 22, said reference signal controller arranged to apply said temporary change to said generated reference signal.

32. The reference signal generator as claimed in claim 31, wherein said IGBT is replaced with a JFET, MOSFET or SiC transistor, and said collector-emitter voltage is a drain-source voltage.

33. An active voltage control circuit including a reference signal generator as claimed in claim 31.

34. The active voltage control circuit as claimed in claim 33, wherein said IGBT is replaced with a JFET, MOSFET or SiC transistor, and said collector-emitter voltage is a drain-source voltage.

35. A power switching circuit comprising a reference signal controller as claimed in claim 22 and comprising said series-connected power switching devices, wherein said power switching devices comprise a plurality of IGBTs, the power switching circuit comprising a plurality of active voltage control circuits each arranged to control a respective said IGBT dependent on said reference signal.

36. The power switching circuit as claimed in claim 35, wherein said IGBT is replaced with a JFET, MOSFET or SiC transistor, and said collector-emitter voltage is a drain-source voltage.

37. An inverter comprising a reference signal controller as claimed in claim 22, and said series-connected power switching devices, wherein said power switching devices comprise groups of one or more IGBTs, the inverter comprising a plurality of active voltage control circuits each to control a respective said IGBT, the inverter arranged to provide a plurality of said reference signals, each said reference signal to control the active voltage control circuits of a said group, the reference signal controller or generator to provide said temporarily change control of at least one said reference signal during a said off period.

38. The inverter as claimed in claim 37, comprising a voltage monitor to monitor at least one voltage in said series connection, a selector to select one or more said reference signals on the basis of said monitoring, said reference signal controller or generator arranged to perform said temporary change control on the or each said selected reference signal during a said off period.

39. The inverter as claimed in claim 37, wherein said IGBT is replaced with a JFET, MOSFET or SiC transistor, and said collector-emitter voltage is a drain-source voltage.

40. A reference signal generator configured to generate a reference signal for an active voltage control circuit, said reference signal for voltage clamping an IGBT such that during a off period said reference signal when input to a said active voltage control circuit limits collector-emitter voltage of said IGBT to be within a range, the reference signal having an off period comprising a temporary change of said reference signal from an initial value to a temporary clamp value, said temporary change for controlling sharing of voltage among series-connected power switching devices including said IGBT when each of said devices is in a substantially non-conducting state.

41. An active voltage control circuit including a reference signal generator as claimed in claim 40.

42. A power switching circuit including a reference signal generator as claimed in claim 40, comprising said series-connected power switching devices, wherein said power switching devices comprise a plurality of IGBTs, the power switching circuit comprising a plurality of active voltage control circuits each arranged to control a respective said IGBT dependent on said reference signal.

43. An inverter comprising a reference signal generator as claimed in claim 40, and said series-connected power switching devices, wherein said power switching devices comprise groups of one or more IGBTs, the inverter including a plurality of active voltage control circuits each to control a respective said IGBT, the inverter arranged to provide a plurality of said reference signals, each said reference signal to control the active voltage control circuits of a said group, the reference signal controller or generator to provide said temporarily change control of at least one said reference signal during a said off period.

44. The inverter as claimed in claim 43, including a voltage monitor to monitor at least one voltage in said series connection, a selector to select one or more said reference signals on the basis of said monitoring, said reference signal controller or generator arranged to perform said temporary change control on the or each said selected reference signal during a said off period.

45. A power switching device controller for controlling sharing of voltage among series-connected power switching devices, wherein at least one said device is an insulated gate bipolar transistor (IGBT), the apparatus comprising:
means for controlling the IGBT dependent on a reference signal and collector or emitter voltage of the IGBT such that during an off period of said IGBT said reference signal limits an absolute value of collector-emitter voltage of said IGBT to be within a range; and
means for control to temporarily change during said limiting said reference signal from an initial value to a temporary clamp value to reduce said range, said change when each of said devices is in a substantially non-conducting state.

46. The power switching device controller as claimed in claim 45, wherein said IGBT is replaced with a JFET, MOSFET or SiC transistor, and said collector-emitter voltage is a drain-source voltage.
